(19) United States
(12) Patent Application Publication
(10) Pub. No.: US 2026/0060093 A1
(43) Pub. Date: Feb. 26, 2026

(54) SEMICONDUCTOR PACKAGE

(71) Applicant: Samsung Electronics Co., Ltd., Suwon-si (KR)

(72) Inventors: SUNGMIN BAEK, Suwon-si (KR); SEUNG-WAN KIM, Suwon-si (KR); JOOHYUNG LEE, Suwon-si (KR)

(21) Appl. No.: 19/202,157

(22) Filed: May 8, 2025

(30) Foreign Application Priority Data
Aug. 20, 2024 (KR) 10-2024-0111196

(51) Int. Cl. H01L 23/64; H01L 23/498

(52) U.S. Cl. CPC H01L 23/642; H01L 23/49816; H01L 23/49838

(57) ABSTRACT

The present disclosure relates to a semiconductor package, and a semiconductor package according to an embodiment includes: a first redistribution layer including a first redistribution pattern, through which a hole penetrates, a semiconductor chip disposed on the first redistribution layer, a first conductive pad disposed on a bottom surface of the first redistribution layer, and a passive device connected to the first conductive pad. A first part of the first conductive pad overlaps the hole with respect to a top down view, and the remaining part of the first conductive pad overlaps a peripheral portion of the first redistribution pattern on a plane. The peripheral portion surrounds the hole with respect to a top down view.

### CROSS-REFERENCE TO RELATED APPLICATION

This application claims priority to and the benefit of Korean Patent Application No. 10-2024-0111196 filed in the Korean Intellectual Property Office on Aug. 20, 2024, the entire contents of which are incorporated herein by reference.

### BACKGROUND

### 1. Field

The described technology relates generally to a semiconductor package.

### 2. Description of the Related Art

The semiconductor industry is pursuing improvement in integration density such that more passive or active devices can be integrated within a given region. Among these, as the development of technology for miniaturizing a circuit line width of a semiconductor preprocess gradually faces its limits, the semiconductor industry is developing semiconductor packages that protect semiconductor chips on which ICs are formed by making them lighter, thinner, miniaturized, faster, more multifunctional, and having higher integration density, thereby complementing the limits of the semiconductor preprocess.

In the case of a semiconductor package with a high-performance semiconductor chip embedded, problems such as system malfunction and performance deterioration may occur due to voltage noise occurring in a high-frequency band. Therefore, development of a packaging technology that can improve the power integrity (PI) characteristics of the semiconductor package by removing voltage noise is required. For this purpose, a semiconductor chip such as a passive element is mounted on the back of the semiconductor package.

### SUMMARY

According to embodiments, the reliability of the semiconductor package can be improved.

A semiconductor package according to an embodiment includes: a first redistribution layer including a first redistribution pattern, through which a hole penetrates; a semiconductor chip disposed on the first redistribution layer; a first conductive pad disposed on a bottom surface of the first redistribution layer; and a passive device connected to the first conductive pad. With respect to a top down view, a first part of the first conductive pad overlaps the hole, and the remaining part of the first conductive pad overlaps a peripheral portion of the first redistribution pattern. The peripheral portion surrounds the hole with respect to a top down view.

A semiconductor package according to an embodiment includes: a first redistribution layer; a semiconductor chip disposed on the first redistribution layer; a first conductive pad that contacts a bottom surface of the first redistribution layer; and a passive device connected to the first conductive pad. The first redistribution layer comprises: a first redistribution pattern, through which a hole penetrates, and a first insulation layer that fills the hole. A first portion of the first conductive pad is in contact with a bottom surface of the first insulation layer positioned within the hole. The remaining portion of the first conductive pad is in contact with a bottom surface of a peripheral portion of the first redistribution pattern. The peripheral portion surrounds the hole with respect to a top down view.

A semiconductor package according to an embodiment includes: a first redistribution layer; a first chip disposed on a first surface of the first redistribution layer; a second redistribution layer disposed on the first chip; a conductive post that connects the first redistribution layer and the second redistribution layer; a first conductive pad and a second conductive pad disposed on the first redistribution layer; a second chip disposed on a second surface of the first redistribution layer; and a first conductive terminal protruding from a bottom surface of the second conductive pad. The first and second surfaces of the first redistribution layer faces away from each other. The second chip includes a second conductive terminal connected to the first conductive pad. The first redistribution layer comprises: a first redistribution pattern, through which a hole penetrates, and a first insulation layer disposed in the hole and including a material having an elastic modulus smaller than an elastic modulus of the first redistribution pattern. A first portion of the first conductive pad overlaps the first insulation layer disposed within the hole with respect to a top down view, and the remaining portion of the first conductive pad overlaps the a peripheral portion of the first redistribution pattern, and the peripheral portion surrounds the hole with respect to a top down view.

According to embodiments, the reliability of the semiconductor package can be improved.

### BRIEF DESCRIPTION OF THE DRAWINGS

FIG. 1 is a cross-sectional view of a semiconductor package according to an embodiment.

FIG. 2 is an enlarged cross-sectional view of the region S1 of FIG. 1.

FIG. 3 is a layout diagram of a passive element of the semiconductor package according to an embodiment.

FIG. 4 is a bottom view of a first redistribution pattern and a first conductive pad of the semiconductor package according to an embodiment.

FIG. 5 and FIG. 6 are enlarged bottom views of the region S2 of FIG. 4.

FIG. 7 is a cross-sectional view that shows the passive element, a first redistribution structure, and an external connection structure of the semiconductor package according to an embodiment.

FIG. 8 to FIG. 10 are bottom views corresponding to the region S2 of FIG. 4, showing a first redistribution pattern and a first conductive pad according to some embodiments.

FIG. 11 to FIG. 13 are cross-sectional views corresponding to the region S1 of FIG. 1, showing semiconductor packages according to some embodiments.

FIG. 14 is a cross-sectional view of a semiconductor package according to some embodiments.

FIG. 15 to FIG. 25 are cross-sectional views illustrating a manufacturing method of a semiconductor package of an embodiment.

### DETAILED DESCRIPTION

Hereinafter, with reference to the accompanying drawing, various embodiments of the present disclosure are described in detail and thus a person of ordinary skill in the art to which the present disclosure belongs can easily practice the invention. As those skilled in the art would realize, the described embodiments may be modified in various different ways, all without departing from the spirit or scope of the present invention.

The drawings and description are to be regarded as illustrative in nature and not restrictive. Like reference numerals designate like elements throughout the specification.

In addition, the size and thickness of each component shown in the drawing are arbitrarily shown for better understanding and ease of description, so the present invention is not necessarily limited to what is shown.

Throughout the specification, when it is described that an element is “connected” to another element, this includes not only cases where it is “directly connected”, but also cases where it is “indirectly connected” through another member. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, throughout the specification, the word “on” a target element will be understood to be positioned above or below the target element, and will not necessarily be understood to be positioned “at an upper side” based on an opposite to gravity direction. When an element is referred to as “contacting” or “in contact with” another element (or using any form of the word “contact”), there are no intervening elements present at the point of contact.

Further, throughout the specification, the phrase “on a plane” means viewing a target portion from the top (i.e., with respect to a top down view), and the phrase “on a cross-section” means viewing a cross-section formed by vertically cutting a target portion from the side.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

Items described in the singular herein may be provided in plural, as can be seen, for example, in the drawings. Thus, the description of a single item that is provided in plural should be understood to be applicable to the remaining plurality of items unless context indicates otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

It will be understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

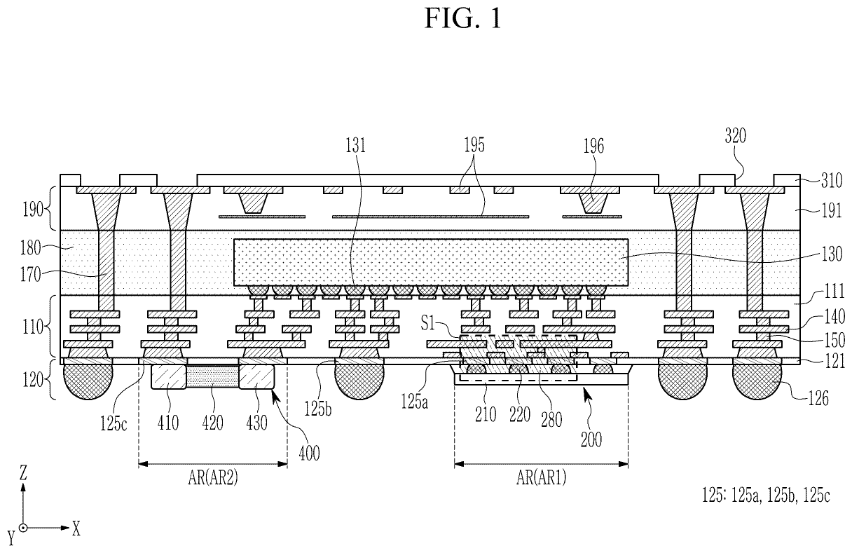

Hereinafter, referring to FIG. 1 to FIG. 3, a semiconductor package device according to an embodiment will be described.

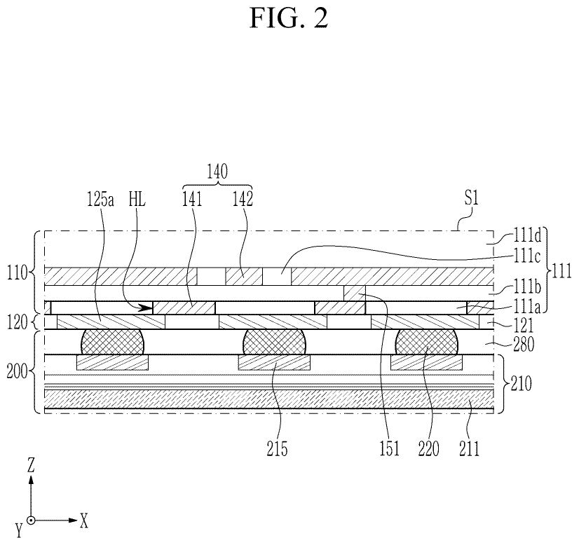

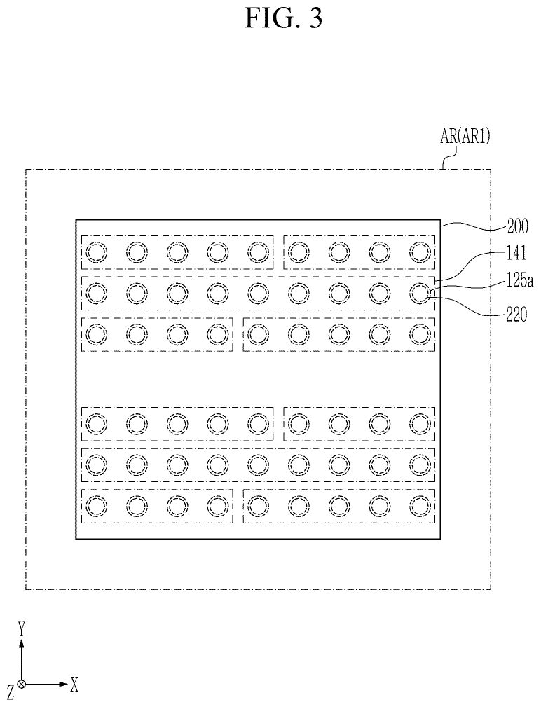

FIG. 1 is a cross-sectional view of a semiconductor package according to an embodiment. FIG. 2 is an enlarged cross-sectional view of the region S1 of FIG. 1. FIG. 3 is a layout diagram of a passive element of the semiconductor package according to an embodiment.

Referring to FIG. 1 and FIG. 2, a semiconductor package according to an embodiment may include a first redistribution structure 110, an external connection structure 120 disposed on a bottom surface of the first redistribution structure 110, a passive element (or a passive device) 200 connected with (to) the external connection structure 120, and a semiconductor chip 130 disposed on the first redistribution structure 110. The external connection structure 120 may be disposed on the bottom surface of the first redistribution structure 110. The external connection structure 120 may include a pad insulation layer 121, conductive pads 125, and a main bump (or a conductive terminal) 126.

In an embodiment, the semiconductor package may include a fan-out wafer level package (FOWL P) or a fan-out panel level package (FOPLP). In an embodiment, the semiconductor package may include a package on package (POP).

In the semiconductor package according to an embodiment, at least one passive element 200 may be surface-mounted on one side (surface) of the first redistribution structure 110. In an embodiment, the first redistribution structure 110 may include a mounting region AR. The mounting region AR may refer to a region where the passive element 200 and/or an electronic element 400, which will be described later, are connected or disposed. For example, in a first mounting region AR1, the passive element 200 to be described later may be electrically connected to the first redistribution structure 110, and in a second mounting region AR2, the electronic element 400 to be described later may be electrically connected to the first redistribution structure 110. Accordingly, the signal integrity (SI) and/or power integrity (PI) characteristics of the semiconductor package can be improved.

The first redistribution structure 110 may be a redistribution layer which is a composite layer including a plurality of insulation layers 111, a plurality of redistribution patterns 140, and a plurality of redistribution vias 150.

The plurality of insulation layers 111 may protect and insulate the plurality of redistribution vias 150 and the plurality of redistribution patterns 140. On upper surfaces of the plurality of insulation layers 111, the semiconductor chip 130 and a conductive post 170, which will be described later, may be disposed. The external connection structure 120, which will be described later, may be disposed on bottom surfaces of the plurality of insulation layers 111.

The plurality of insulation layers 111 may include insulating resin. The insulating resin may include a thermosetting resin such as epoxy resin, a thermoplastic resin such as polyimide, or a resin impregnated/immersed with inorganic fillers and/or glass fibers (glass fiber, glass cloth, glass fabric) (e.g., photosensitivity resin such as prepreg, ABF, FR-4, BT, or photo-imageable dielectric (PID)). The plurality of insulation layers 111 may be stacked in a vertical direction. In some embodiments, the vertical direction may mean a thickness direction (i.e., third direction (Z direction)) of the first redistribution structure 110.

The plurality of insulation layers 111 according to an embodiment may include a first insulation layer 111a to a fourth insulation layer 111d.

The first insulation layer 111a may be disposed on the external connection structure 120, which will be described later. The first insulation layer 111a may be disposed directly on an upper surface of the external connection structure 120, which will be described later. In an embodiment, the first insulation layer 111a may mean an insulation layer of the first redistribution structure 110 contacting the upper surface of the external connection structure 120. The first insulation layer 111a may include insulating resin. In an embodiment, the first insulation layer 111a may include a material having a predetermined elastic modulus.

The second insulation layer 111b to the fourth insulation layer 111d may be sequentially disposed on the first insulation layer 111a. The second insulation layer 111b may be disposed on an upper surface of the first insulation layer 111a, the third insulation layer 111c may be disposed on an upper surface of the second insulation layer 111b, and the fourth insulation layer 111d may be disposed on an upper surface of the third insulation layer 111c.

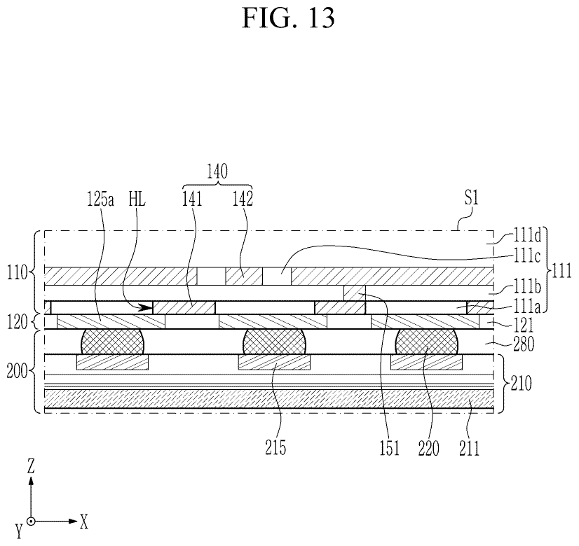

The second insulation layer 111b to the fourth insulation layer 111d may include the same material as the first insulation layer 111a, but the invention is not limited thereto, and may include a different material from the first insulation layer 111a. In an embodiment, the second insulation layer 111b to the fourth insulation layer 111d may include a material having the same elastic modulus as the first insulation layer 111a, but the invention is not limited thereto. For example, the second insulation layer 111b to the fourth insulation layer 111d may include a material having an elastic modulus greater than that of the first insulation layer 111a. This will be described later with reference to FIG. 13.

Although it is illustrated in FIG. 2 that the first redistribution structure 110 includes four insulation layers 111, but the invention is not limited thereto. For example, the first redistribution structure 110 may include five or more insulation layers 111. Alternatively, the first redistribution structure 110 may include three or less insulation layers 111. Depending on the process, the boundaries between the plurality of insulation layers 111 may be unclear.

The plurality of redistribution patterns 140 may extend in a horizontal direction (e.g., first direction (X direction) and/or a second direction (Y direction)). The plurality of redistribution patterns 140 may be electrically connected with the external connection structure 120. The plurality of redistribution patterns 140 may include a conductive material. The plurality of redistribution patterns 140 may include a metallic material including, for example, copper (Cu), aluminum (Al), silver (Ag), tin (Sn), gold (Au), nickel (Ni), lead (Pb), titanium (Ti), or an alloy thereof. In an embodiment, the plurality of redistribution patterns 140 may include a material having a greater elastic modulus than that of the plurality of insulation layers 111. In an embodiment, the plurality of redistribution patterns 140 may include a first redistribution pattern 141 and a second redistribution pattern 142.

The first redistribution pattern 141 may be disposed on the external connection structure 120, which will be described later. The first redistribution pattern 141 may contact the external connection structure 120, which will be described later. For example, as shown in FIG. 2, the first redistribution pattern 141 may contact a first conductive pad 125a of the external connection structure 120, which will be described later. The first redistribution pattern 141 may be directly connected to a chip bump (or a conductive terminal) 220 of the passive element 200, which will be described later. In an embodiment, the first redistribution pattern 141 may mean a redistribution pattern of the first redistribution structure 110 that is in contact with the first conductive pad 125a that is electrically connected to the passive element 200 to be described later.

In an embodiment, the first redistribution pattern 141 disposed in the first mounting region AR1 may extend in one direction. For example, as shown in FIG. 3, the first redistribution pattern 141 disposed in the first mounting region AR1 may extend in the first direction (X direction). Accordingly, in the first mounting region AR1, the first redistribution pattern 141 may be electrically connected to chip bumps 220 of two or more passive elements 200 arranged along the first direction (X direction). However, this is not restrictive, and the first redistribution pattern 141 in the first mounting region AR1 may extend in a direction different from the first direction (X direction).

For better understanding and ease of description, in FIG. 3, only the passive element 200, the first redistribution pattern 141, and the first conductive pad 125a that are disposed in the first mounting region AR1 are illustrated, and other constituent elements are omitted.

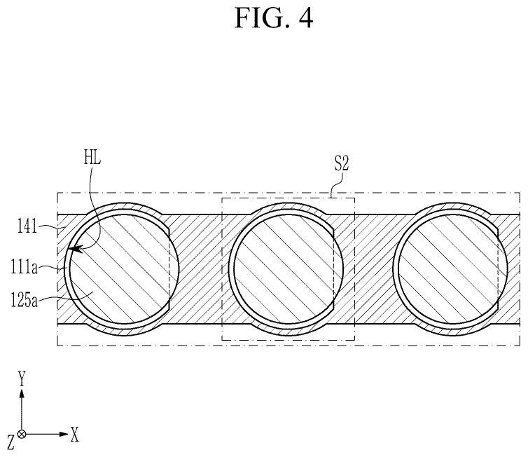

The first redistribution pattern 141 may include a hole HL penetrating the first redistribution pattern 141. The hole HL may be surrounded by a portion of the first redistribution pattern 141 extending in the first direction (X direction). The first insulation layer 111a may be disposed in the hole HL. In this case, the first redistribution pattern 141 may include a material having an elastic modulus greater than that of the first insulation layer 111a. In an embodiment, the hole HL may overlap the plurality of insulation layers 111 in a third direction (Z direction) (or on a plane). For example, the hole HL may completely overlap the first insulation layer 111a in the third direction (Z direction). As another example, the hole HL may completely overlap the first to third insulation layer 111a to 111c or the first to fourth insulation layers 111a to 111d in the third direction (Z direction). A detailed description of the hole HL will be provided later with reference to FIG. 4 to FIG. 7.

The first redistribution pattern 141 may be disposed in the same layer as the first insulation layer 111a. The upper surface of the first redistribution pattern 141 may be disposed at substantially the same level as the upper surface of the first insulation layer 111a, and the bottom surface of the first redistribution pattern 141 may be disposed at substantially the same level as the bottom surface of the first insulation layer 111a. For example, the upper surface of the first redistribution pattern 141 may be disposed at substantially the same distance from the upper surface of the first insulation layer 111a and the upper surface of the first redistribution structure 110. For example, a distance between the bottom surface of the first insulation layer 111a and the upper surface of the first redistribution structure 110 may be the same as a distance between the bottom surface of the first redistribution pattern 141 and the upper surface of the first redistribution structure 110, and a distance between the upper surface of the first insulation layer 111a and the upper surface of the first redistribution structure 110 may be the same as a distance between the upper surface of the first redistribution pattern 141 and the upper surface of the first redistribution structure 110.

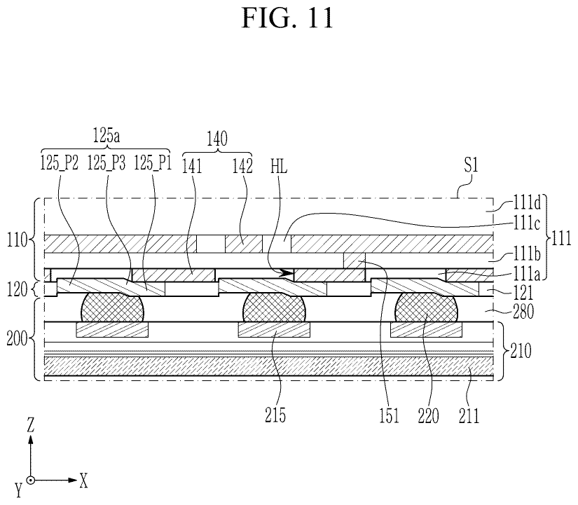

The bottom surface of the first redistribution pattern 141 may be disposed at substantially the same distance from the bottom surface of the first insulation layer 111a and the top surface of the first redistribution structure 110. However, this is not restrictive, and depending on embodiments, the upper surface of the first redistribution pattern 141 may be disposed at a different level from the upper surface of the first insulation layer 111a. This will be described later with reference to FIG. 11 to FIG. 13.

The second redistribution pattern 142 may be disposed on the first redistribution pattern 141. The second redistribution pattern 142 may be disposed on the upper surface of the first redistribution pattern 141. The second redistribution pattern 142 may penetrate the third insulation layer 111c. The second redistribution pattern 142 may be disposed in the same layer as the third insulation layer 111c.

The number of layers of the plurality of redistribution patterns 140 may be determined according to the number of layers of the plurality of insulation layers 111, and may include more or fewer layers than those shown in FIG. 2.

The plurality of redistribution vias 150 may be respectively disposed between the plurality of redistribution patterns 140, between the plurality of redistribution patterns 140 and the conductive pads 125 of the external connection structure 120, and between the plurality of redistribution patterns 140 and the conductive post 170. The plurality of redistribution vias 150 may electrically connect between the plurality of redistribution patterns 140, between the plurality of redistribution patterns 140 and the conductive pads 125, and between the plurality of redistribution patterns 140 and the conductive post 170 in the third direction (Z direction). For example, as shown in FIG. 2, the plurality of redistribution vias 150 may include a first redistribution via 151 may electrically connect between the first redistribution pattern 141 and the second redistribution pattern 142.

The first redistribution structure 110 of the semiconductor package according to an embodiment may further include a barrier conductive layer disposed on the bottom surfaces of the plurality of redistribution patterns 140 and the bottom surfaces and side surfaces of the plurality of redistribution vias 150. The barrier conductive layer may be a plating seed layer on which the plurality of redistribution patterns 140 and the plurality of redistribution vias 150 are deposited.

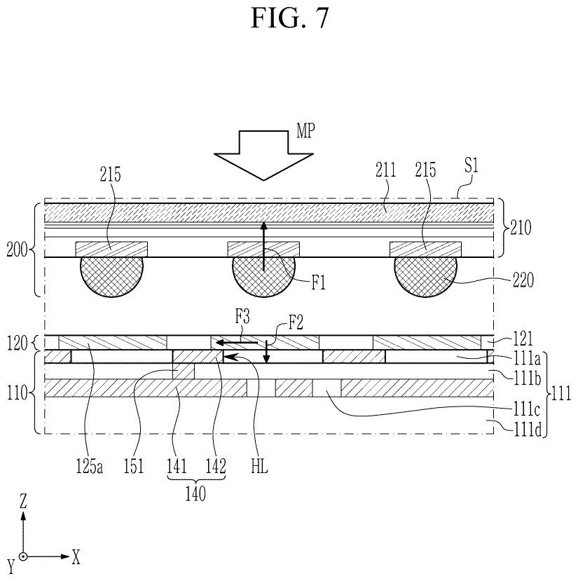

The pad insulation layer 121 may be disposed on the bottom surface of the first redistribution structure 110. The pad insulation layer 121 may be disposed directly on the bottom surface of the first redistribution pattern 141 and the bottom surface of the first insulation layer 111a. The pad insulation layer 121 may include at least one of a silicon-based insulator such as silicon oxide or silicon nitride, a polymer such as PBO, BCB or polyimide, and a nitride such as PSG or BPSG. In an embodiment, an elastic modulus of a material forming the pad insulation layer 121 may be greater than or equal to the elastic modulus of the material forming the first insulation layer 111a. By this configuration of the materials of the pad insulation layer 121 and the first insulation layer 111a, when the passive element 200 is mounted on the first conductive pad 125a, the mounting pressure (MP in FIG. 7) applied within the passive element 200 may be reduced.

The conductive pads 125 may be embedded or formed on the bottom surface of the pad insulation layer 121. The conductive pads 125 may penetrate the pad insulation layer 121. The conductive pads 125 may be electrically connected to the first redistribution pattern 141 through the pad insulation layer 121. The conductive pads 125 may be electrically connected to the first redistribution structure 110.

In an embodiment, the conductive pads 125 may include a first conductive pad 125a disposed on the first mounting region AR1, a third conductive pad 125c disposed on the second mounting region AR2, and a second conductive pad 125b disposed in a region other than the mounting region A R. For example, the passive element 200, which will be described later, is electrically connected with the first conductive pad 125a in the first mounting region AR1, and the electronic element 400, which will be described later, is electrically connected with the third conductive pad 125c in the second mounting region AR2.

For example, the first conductive pad 125a may be under bump metallization (UBM) on which a conductive bump (e.g., chip bum 22 and main bump 126) is formed.

The first conductive pad 125a may be used as a landing pad to which the passive element 200 is connected, and the third conductive pad 125c may be used as a landing pad to which the electronic element 400 is connected. The first conductive pad 125a may be electrically connected with the passive element 200 through the chip bump 220, the third conductive pad 125c may be electrically connected with the electronic element 400, and the second conductive pad 125b may be electrically connected with an external device (e.g., a board where a semiconductor package is mounted, and the like) through the chip bump 220.

The first conductive pad 125a may overlap the hole HL of the first redistribution pattern 141 in the third direction (Z direction). A part (portion) of the first conductive pad 125a may overlap the first redistribution pattern 141 in the third direction (Z direction), and the remaining part may overlap with the first redistribution pattern 141 in the third direction (Z direction). For example, on a plane, the remaining part may overlap a peripheral portion of the first redistribution pattern 141, and the peripheral portion may surround the hole HL. This will be described later with reference to FIG. 4 to FIG. 7. Depending on embodiments, the second conductive pad 125b and the third conductive pad 125c may also overlap the hole HL of the first redistribution pattern 141 in the third direction (Z direction).

The first conductive pad 125a may be in contact with the bottom surface of the first redistribution pattern 141 and the bottom surface of the first insulation layer 111a. On a plane, the first conductive pad 125a may have a circular shape.

The first conductive pad 125a and the second conductive pad 125b may include an electrically conductive material. For example, the first conductive pad 125a and the second conductive pad 125b may include at least one of Cu, Ni, Au, Cr, Al, Ag, Zn, and Fe. In an embodiment, the elastic modulus of the material constituting the first conductive pad 125a may be greater than the elastic modulus of the material constituting the pad insulation layer 121. In addition, the elastic modulus of the material constituting the first conductive pad 125a may be greater than the elastic modulus of the material constituting the first insulation layer 111a.

The main bump 126 may electrically connect the semiconductor package to an external device. For example, the second conductive pad 125b of the semiconductor package may be electrically connected to an external device (e.g., a board where a semiconductor package is mounted, and the like) through the main bump 126.

The passive element 200 may be disposed on the bottom surface of the first redistribution structure 110. The passive element 200 may be disposed on the first mounting region AR1 of the first redistribution structure 110. The passive element 200 may be connected to the first conductive pad 125a disposed on the first mounting region AR1. The passive element 200 may be electrically connected to the first redistribution structure 110 through the first conductive pad 125a.

In an embodiment, the passive element 200 may be a capacitor element. For example, the passive element 200 may be a silicon capacitor, but the invention is not limited thereto. As another example, the passive element 200 may include or be a multilayer ceramic capacitor (MLCC) or a low inductance ceramic capacitor (LICC), or may include an inductor, beads, and the like.

Further referring to FIG. 2, the passive element 200 of the semiconductor package according to an embodiment may include a substrate (or capacitor die) 210 including a porous structure (or a porous layer) 211 and a chip pad 215, a chip bump 220 disposed on one side of the substrate 210, and a sealing material 280 surrounding the chip bump 220.

The porous structure 211 of the passive element 200 may include a material layer that forms a capacitor. For example, the porous structure 211 may include or be part of a silicon capacitor. The porous structure 211 may include a first electrode and a second electrode, and a dielectric layer disposed between the first electrode and the second electrode which form a capacitor. In an embodiment, the porous structure 211 may be formed of a porous material layer. The first electrode, the second electrode, and the dielectric layer (which constitute the capacitor) may be sequentially disposed along surfaces of pores within the porous material layer. Accordingly, the surface area of the porous structure 211 may increase due to the pore, and the area where the capacitor is placed may increase. For example, due to the pores, the effective area of the capacitor and the capacitance per unit area of the capacitor may be increased. For example, the porous structure 211 may include anodic aluminum oxide (AAO). Meanwhile, since the porous structure 211 contains pores, it may be vulnerable to external pressure. Although the porous structure 211 of the passive element 200 may be susceptible to external forces (for example, pressure applied when attaching the passive element 200 to the first redistribution structure 110), a problem resulting from the susceptibility (for example causing crack of the porous structure 211) may be addressed, as described later.

The chip pad 215 may be embedded within the substrate 210. The chip pad 215 may be electrically connected to the first conductive pad 125a via the chip bump 220. By the chip bump 220, the passive element 200 may be electrically connected to the first conductive pad 125a. In an embodiment, the chip bump 220 may overlap the hole HL of the first redistribution pattern 141 in the third direction (Z direction). The sealing material 280 may surround the chip bump 220 on one side of the substrate 210. The sealing material 280 may seal the chip bump 220.

Referring back to FIG. 1, the semiconductor package according to an embodiment may further include the electronic element (or electrical element) 400.

The electronic element 400 may be disposed on the bottom surface of the first redistribution structure 110. The electronic element 400 may be disposed in the second mounting region AR2 of the first redistribution structure 110. The electronic element 400 may be connected to the third conductive pad 125c disposed in the second mounting region AR2. The electronic element 400 may be electrically connected to the first redistribution structure 110 via the third conductive pad 125c.

In an embodiment, the electronic element 400 may be a capacitor element. For example, the electronic element 400 may be a low inductance ceramic capacitor (LICC). The electronic element 400 may include a first electrode 410 and a second electrode 430 connected to the conductive pads 125c, and a dielectric layer 420 disposed between the first electrode 410 and the second electrode 430, but the invention is not limited thereto. As another example, the electronic element 400 may include (or be) a multilayer ceramic capacitor (MLCC) or an inductor (inductor), beads, and the like.

The semiconductor chip 130 may be mounted on the upper surface of the first redistribution structure 110. In an embodiment, the semiconductor chip 130 may include a 3-dimensional IC (3D IC) structure. For example, the semiconductor chip 130 may be a plurality semiconductor dies. In addition, in an embodiment, the semiconductor chip 130 may include a system on chip (SOC). For example, the semiconductor chip 130 may include at least one of a central processing unit (CPU), a graphic processing unit (GPU), a memory, a controller, a codec, a sensor, and a communication chip.

The semiconductor chip 130 may be electrically connected to the first redistribution structure 110 through a connection member (conductive terminal) 131. In an embodiment, the connection member 131 may include a micro bump.

The semiconductor package according to an embodiment may further include a molding member 180 that surrounds the conductive post 170 and the semiconductor chip 130 disposed on the first redistribution structure 110.

The conductive post 170 may be disposed on the upper surface of the first redistribution structure 110. The conductive post 170 may be disposed through the molding member 180. A side surface of the conductive post 170 may be surrounded by the molding member 180. The conductive post 170 may be disposed between the first redistribution structure 110 and the second redistribution structure 190. The conductive post 170 may electrically connect the first redistribution structure 110 and the second redistribution structure 190. For example, the conductive post 170 may electrically connect the plurality of redistribution vias 150 of the first redistribution structure 110 and the plurality of upper redistribution vias 196 of the second redistribution structure 190.

The molding member 180 may mold the semiconductor chip 130 and the conductive post 170 on the first redistribution structure 110.

The semiconductor package according to an embodiment may further include a second redistribution structure 190.

The second redistribution structure 190 may be disposed on the molding member 180. The second redistribution structure 190 may be a second redistribution layer which is a composite layer including an upper insulation layer 191, a plurality of upper redistribution vias 196 disposed in the upper insulation layer 191, and plurality of upper redistribution patterns 195.

The upper insulation layer 191 may protect and insulate the plurality of upper redistribution vias 196 and the plurality of upper redistribution patterns 195. The upper insulation layer 191 may be disposed on upper surfaces of the conductive post 170 and the molding member 180. The upper insulation layer 191 may contain the same materials as the plurality of insulation layers 111, but the invention is not limited thereto.

The plurality of upper redistribution patterns 195 may extend in the horizontal direction (e.g., first direction (X direction) and/or second direction (Y direction)). The plurality of upper redistribution patterns 195 may be electrically connected between the plurality of upper redistribution vias 196 in the horizontal direction (e.g., first direction (X direction) and/or the second direction (Y direction)).

The plurality of upper redistribution vias 196 may be disposed between the conductive post 170 and the plurality of upper redistribution patterns 195. The plurality of upper redistribution vias 196 may be electrically connected to a pair of the plurality of upper redistribution patterns 195. The upper redistribution via 196 may electrically connect the conductive post 170 and the upper redistribution pattern 195 in the third direction (Z direction). In an embodiment, the upper insulation layer 191 and the plurality of upper redistribution patterns 195 may be formed as multiple layers or as a single layer. For example, the plurality of upper redistribution patterns 195 may be disposed at the same height level in Z the direction, the upper insulation layer 191 may be a single layer disposed at the same height level in Z the direction, and the upper redistribution vias 196 may be formed to penetrate the upper insulation layer 191.

The semiconductor package according to an embodiment of the second redistribution structure 190 may further include a capping layer 310 disposed on the second redistribution structure 190. The capping layer 310 may cover the upper surface of the second redistribution structure 190. The capping layer 310 may include an opening 320 through which external elements may be electrically connected to the second redistribution structure 190.

Hereinafter, referring to FIG. 4 to FIG. 6, the first redistribution pattern and the first conductive pad of the semiconductor package according to an embodiment will be described.

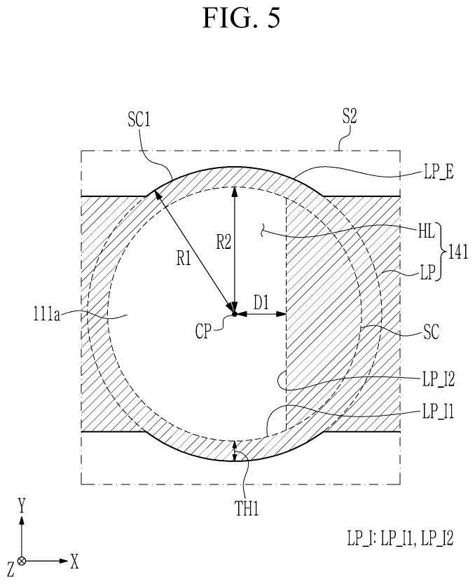

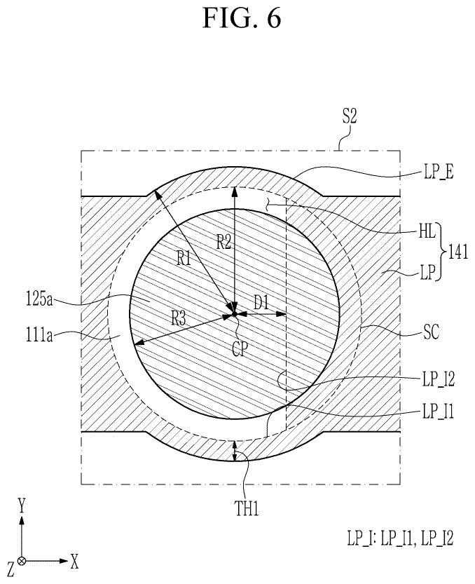

FIG. 4 is a bottom view of the first redistribution pattern and the first conductive pad of the semiconductor package according to an embodiment. FIG. 5 and FIG. 6 are enlarged bottom views of the region S2 of FIG. 4. For better understanding and ease of description, in FIG. 4 and FIG. 6, only the first redistribution pattern 141, the first insulation layer 111a, and the first conductive pad 125a are illustrated. In addition, in FIG. 5, only the first redistribution pattern 141 and the first insulation layer 111a are illustrated, and the first conductive pad 125a is omitted.

Referring to FIG. 4 and FIG. 5, the first redistribution structure may include a line portion LP and the hole HL disposed in the line portion LP. The line portion LP may be the first redistribution pattern 141, or a portion of the first redistribution pattern 141.

The line portion LP may extend in the first direction (X direction). The line portion LP may extend in the first direction (X direction) and may be electrically connected to the plurality of first conductive pads 125a. The hole HL may be disposed in the line portion LP. The Hole HL may be defined by an inner surface LP_I of line portion LP. The line portion LP may include a portion protruded in the second direction (Y direction). For example, the line portion LP may be protruded in the second direction (Y direction) from a part where the hole HL is positioned.

As the hole HL is disposed within the line portion LP, the line portion LP may include an exterior surface (or an exterior boundary) LP_E and an interior surface (or an interior boundary) LP_I. The interior surface LP_I of the line portion LP may include a first interior surface LP_I1 and a second interior surface LP_I2. In a portion where the hole HL is disposed, the exterior surface LP_E and the interior surface LP_I of the line portion LP may include curved surfaces. For example, a part of the exterior surface LP_E of the line portion LP may have a circular shape at the portion where the hole HL is disposed. In addition, a first interior surface LP_I1 of the line portion LP may have a part of a circular shape. In this case, a part of the exterior surface LP_E of the line portion LP may have a circular shape having a first diameter (or a first radius of curvature) R1, and a part of the first interior surface LP_I1 of the line portion LP may have a circular shape having a second diameter (or a second radius of curvature) R2 smaller than the first diameter R1. Here, the first diameter R1 may be greater than 44 μm and less than or equal to 49 μm, and the second diameter R2 may be greater than 40 μm and less than or equal to 45 μm.

Accordingly, the line portion LP at the portion where the hole HL is disposed may have a first thickness (or width) TH1. The first thickness TH1 may correspond to a difference between the first diameter R1 and the second diameter R2. For example, the first thickness TH1 may be 4 μm to 8 μm, but the invention is not limited thereto.

Hereinafter, for better understanding and ease of explanation, a virtual circle forming the first interior surface LP_I1 of the line portion LP is defined as a referential circle SC. The referential circle SC may have a second diameter R2 with its center point CP as a reference. The first interior surface LP_I1 of the line portion LP may have a circular shape with a second diameter R2 that is the same as the referential circle SC.

In an embodiment, the line portion LP may be protruded from the referential circle SC toward the center point CP of the referential circle SC. For example, as shown in FIG. 4, line portion LP may protrude toward the center point CP from one side along the first direction (X direction) of the referential circle SC. The second interior surface LP_I2 of the line portion LP protruding from the referential circle SC toward the center point CP of the referential circle SC may be extended in one direction. For example, the second interior surface LP_I2 of the line portion LP may extend in the second direction (Y direction), but the invention is not limited thereto. Here, the second interior surface LP_I2 of the line portion LP may refer to a side surface of a part of the line portion LP protruding from the referential circle SC toward the center point CP of the referential circle SC.

In this case, a first distance D1 along the first direction (X direction) from the center point CP of the referential circle SC to the second interior surface LP_I2 of the line portion LP may be greater than 0 μm and less than 40 μm. Preferably, the first distance D1 along the first direction (X direction) from the center point CP of the referential circle SC to the second interior surface LP_I2 of the line portion LP may be greater than 15 μm and less than 37.5 μm. In this range, the mounting pressure (MP of FIG. 7) applied within the passive element 200 may be reduced when the passive element 200 is mounted on the first conductive pad 125a while securing the contact area between the first conductive pad 125a and the first redistribution pattern 141.

The hole HL may be disposed in the line portion LP. The hole HL may be surrounded by the line portion LP. A side wall of hole HL may be defined by the line portion LP. For example, the side wall of the hole HL may be defined by the first interior surface LP_I1 and the second interior surface LP_I2 of the line portion LP. The first insulation layer 111a may be disposed in the hole HL. The first insulation layer 111a may fill the hole HL.

In an embodiment, the hole HL may overlap the plurality of insulation layers 111 in the third direction (Z direction). For example, the hole HL may completely overlap the first insulation layer 111a in the third direction (Z direction). As another example, the hole HL may completely overlap the first to third insulation layers 111a to 111c in the third direction (Z direction). The hole HL may overlap the second insulation layer 111b and the third insulation layer 111c in the third direction (Z direction), and may not overlap in the third direction (Z direction) the second redistribution pattern 142 that is disposed on the same layer as the third insulation layer 111c. In this case, since the elastic modulus of the material constituting the plurality of insulation layers 111 is smaller than the elastic modulus of the material constituting the plurality of redistribution patterns 140, when the passive element 200 is mounted on the first conductive pad 125a, the mounting pressure (MP of FIG. 7) applied within the passive element 200 can be effectively reduced. As another example, the hole HL may completely overlap the first to fourth insulation layers 111a to 111d in the third direction (Z direction).

On a plane, the hole HL may have a circular segment shape. Here, a circular segment is a shape composed of a chord, which is a line segment connecting two arbitrary points on the referential circle SC, and an arc connecting the two arbitrary points. A part of the side wall of the hole HL may include a curved surface on a plane. For example, as shown in FIG. 4, the side wall of the hole HL may have a part of a circular shape having a second diameter R2, defined by the first interior surface LP_I1 of the line portion LP. The side wall of the hole HL may have another part, which extends along a line (in the second direction (Y direction)) defined by the second interior surface LP_I2 of the line portion LP.

In an embodiment, the maximum width of the hole HL along the first direction (X direction) may be greater than 42 μm and less than 82 μm. Preferably, on a plane, the maximum width of the hole HL along the first direction (X direction) may be greater than 57 μm and less than 79.5 μm. In this range, while securing the contact area between the first conductive pad 125a and the first redistribution pattern 141, the mounting pressure (MP of FIG. 7) applied within the passive element 200 can be reduced when the passive element 200 is mounted on the first conductive pad 125a.

Further referring to FIG. 6, the first conductive pad 125a may be disposed on the hole HL. A portion of the first conductive pad 125a may overlap the hole HL in the third direction (Z direction), and the remaining portion may overlap the line portion LP in the third direction (Z direction). A part of the first conductive pad 125a may overlap the first insulation layer 111a disposed within the hole HL in the third direction (Z direction), and the remaining part may overlap the line portion LP in the third direction (Z direction). In an embodiment, the elastic modulus of the material constituting the first insulation layer 111a may be smaller than the elastic modulus of the material constituting the first redistribution pattern 141. Therefore, the first conductive pad 125a may overlap the first insulation layer 111a having a relatively small elastic modulus and the line portion LP having a relatively large elastic modulus in the third direction (Z direction).

In this case, the area of the portion where the first conductive pad 125a overlaps the hole HL in the third direction (Z direction) may be larger than the area of the portion where the first conductive pad 125a overlaps the line portion LP in the third direction (Z direction).

For example, on a plane, a portion of the first conductive pad 125a may overlap the hole HL, and a remaining portion of the first conductive pad 125a may overlap a peripheral portion (which surrounds the hole HL on a plane) of the first redistribution pattern 141. On a plane, the portion of the first conductive pad may occupy a first area, and the remaining portion may occupy a second area, and the first area may be larger than the second area. The portion of the first conductive pad 125a may be in contact with the first insulation layer 111a disposed within the hole HL, the remaining portion of the first conductive pad 125a may be electrically connected to the peripheral portion (which surrounds the hole HL on a plane) of the first redistribution pattern 141. On a plane, the peripheral portion may overlap the area defined by a referential circle SC1, which is defined by the first diameter R1. In some embodiments, on a plane, the peripheral portion may overlap the area defined by the referential circle SC. In some embodiments, on a plane, the peripheral portion may overlap the area defined by the interior surface LP_I.

By this configuration of the first conductive pad 125a, the hole HL and the first redistribution pattern 141, while securing the contact area between the first conductive pad 125a and the first redistribution pattern 141, the mounting pressure (MP of FIG. 7) applied within the passive element 200 can be reduced when the passive element 200 is mounted on the first conductive pad 125a.

In an embodiment, the first conductive pad 125a may be in contact with the line portion LP and the first insulation layer 111a. For example, the first conductive pad 125a may be in contact with a bottom surface of the line portion LP and may be in contact with the bottom surface of the first insulation layer 111a positioned within the hole HL. For example, at least a portion of the first conductive pad 125a may be in contact with a surface of the peripheral portion (which surrounds the hole HL) of the first redistribution pattern.

In an embodiment, on a plane, the first conductive pad 125a may have a circular shape. A third diameter R3 of the first conductive pad 125a may be smaller than the second diameter R2 of the referential circle SC. In an embodiment, the third diameter R3 of the first conductive pad 125a may be 37.5 μm to 40 μm. The first conductive pad 125a may be disposed apart from the first interior surface LP_I1 of the line portion LP. On a plane, the maximum width of the hole HL along the second direction (Y direction) may be greater than the maximum width of the first conductive pad 125a along the second direction (Y direction).

Hereinafter, further referring to FIG. 7, the semiconductor package according to an embodiment will be described.

FIG. 7 is a cross-sectional view that shows the passive element 200, the first redistribution structure 110, and the external connection structure 120 of the semiconductor package according to an embodiment. FIG. 7 shows a case that the passive element 200 is mounted on the first conductive pad 125a.

Further referring to FIG. 7, the passive element 200 may be mounted on the first conductive pad 125a. For example, the chip bump 220 of the passive element 200 may be connected to the first conductive pad 125a and thus may be electrically connected to the first redistribution structure 110. In this case, the chip bump 220 of the passive element 200 may be connected to the first conductive pad 125a by applying a mounting pressure MP having a predetermined amount. Therefore, when the passive element 200 is mounted on the first conductive pad 125a, a first pressure F1 may be applied within the passive element 200 as a reaction. In addition, the porous structure 211 of the passive element 200 may be vulnerable to external pressure as it contains pores, and cracks may occur in the porous structure 211 due to the mounting pressure MP.

A portion of the first conductive pad 125a of the semiconductor package according to an embodiment may overlap the hole HL in the third direction (Z direction), and the remaining portion may overlap the line portion LP in the third direction (Z direction). The elastic modulus of the material constituting the first insulation layer 111a disposed within the hole HL may be smaller than the elastic modulus of the material constituting the first redistribution pattern 141. The first conductive pad 125a may overlap the first insulation layer 111a having a relatively small elastic modulus and the line portion LP having a relatively large elastic modulus in the third direction (Z direction).

Accordingly, when the passive element 200 is mounted on the first conductive pad 125a, the first insulation layer 111a disposed within the hole HL may be easily deformed in response to external pressure (e.g., mounting pressure (MP)) as compared to the line portion LP. For example, when the mounting pressure MP is applied to the passive element 200 so as to be connected to the first conductive pad 125a, at least a portion of the mounting pressure MP may be offset by a deformation force F2 of the first insulation layer 111a and a tensile force F3 of the first conductive pad 125a. Accordingly, the first pressure F1 applied within the passive element 200 of the semiconductor package according to an embodiment can be reduced, and cracks can be prevented from occurring within the passive element 200. Accordingly, the reliability of the semiconductor package according to an embodiment can be improved.

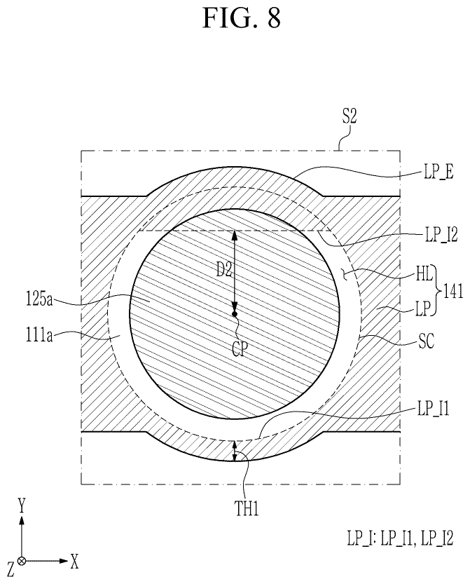

Hereinafter, semiconductor packages according to some embodiments will be described with reference to FIG. 8 to FIG. 13.

FIG. 8 to FIG. 10 are bottom views corresponding to the region S2 of FIG. 4, showing a first redistribution pattern and a first conductive pad according to some embodiments. FIG. 11 to FIG. 13 are cross-sectional views corresponding to the region S1 of FIG. 1, showing semiconductor packages according to some embodiments. For better understanding and ease of description, only the first redistribution pattern 141, the first insulation layer 111a, and the first conductive pad 125a are illustrated in FIG. 8 to FIG. 10.

The embodiments illustrated in FIG. 8 to FIG. 13 are substantially the same as the embodiments illustrated in FIG. 1 to FIG. 7, and therefore a repetitive description thereof will be omitted and the differences will be mainly explained.

Referring to FIG. 8 to FIG. 10, a line portion LP and a hole HL of the semiconductor package according to some embodiments may have various shapes.

For example, as illustrated in FIG. 8, the line portion LP may be protruded toward a center point CP from one side of a referential circle SC along a second direction (Y direction). A second interior surface LP_I2 of the line portion LP may be extended in a first direction (X direction). In this case, a second distance D2 along the second direction (Y direction) from the center point CP of the referential circle SC to the second interior surface LP_I2 of the line portion LP may be greater than 0 μm and less than 40 μm. Preferably, the second distance D2 along the second direction (Y direction) from the center point CP of the referential circle SC to the second interior surface LP_I2 of the line portion LP may be greater than 15 μm and less than 37.5 μm. In this range, while securing a contact area between a first conductive pad 125a and a first redistribution pattern 141, a mounting pressure (MP of FIG. 7) applied within a passive element 200 can be reduced when the passive element 200 is mounted on the first conductive pad 125a.

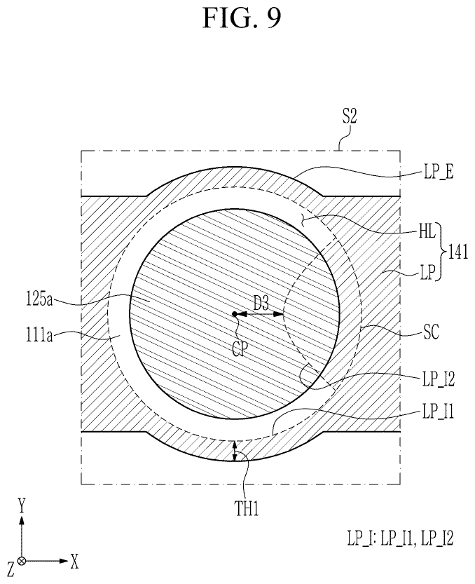

As another example, as illustrated in FIG. 9, the second interior surface LP_I2 of the line portion LP may have a shape protruded toward the center point CP of the referential circle SC. The second interior surface LP_I2 of the line portion LP may have a convex surface shape toward the center point CP of the referential circle SC, but the invention is not limited thereto. In this case, a third distance D3 along a first direction (X direction) from the center point CP of the referential circle SC to the second interior surface LP_I2 of the line portion LP may be greater than 0 μm and less than 40 μm. For example, the third distance D3 along the first direction (X direction) from the center point CP of the referential circle SC to the second interior surface LP_I2 of the line portion LP may mean the minimum distance from the center point CP of the referential circle SC to the second interior surface LP_I2 of the line portion LP along the first direction (X direction).

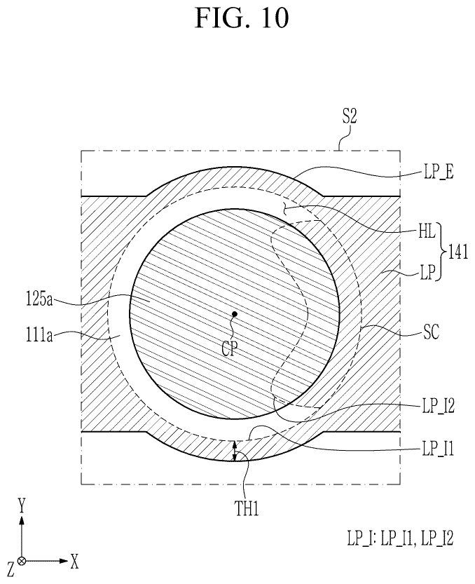

As another example, as illustrated in FIG. 10, the second interior surface LP_I2 of the line portion LP may have a concave shape toward the center point CP of the referential circle SC. The second interior surface LP_I2 of the line portion LP may have a concave surface shape toward the center point CP of the referential circle SC, but the invention is not limited thereto.

Referring to FIG. 11, a first conductive pad 125a of a semiconductor package according to some embodiments may include a first portion 125a_P1 overlapping a line portion LP in a third direction (Z direction), a second portion 125a_P2 overlapping a hole HL in a third direction (Z direction), and a third portion 125a_P3 disposed between the first portion 125a_P1 and the second portion 125a_P2 and inclined from an upper surface of a first redistribution structure 110.

For example, on a plane, a portion of the first conductive pad 125a may overlap the hole HL, and a remaining portion of the first conductive pad 125a may overlap a peripheral portion (which surrounds the hole HL) of the first redistribution pattern 141. A boundary between the portion and the remaining portion of the first conductive pad 125a may be inclined with respect to the upper surface of the first redistribution structure 110 on a cross-section.

In some embodiments, at least a portion of the second portion 125a_P2 may be embedded within the first redistribution structure 110. The second portion 125a_P2 may be disposed at a different height than the first portion 125a_P1. For example, an upper surface of the second portion 125a_P2 may be disposed closer to an upper surface of the first redistribution structure 110 than an upper surface of the first portion 125a_P1, and a bottom surface of the second portion 125a_P2 may be disposed closer to an upper surface of the first redistribution structure 110 than a bottom surface of the first portion 125a_P1.

In some embodiments, the bottom surface of the second portion 125a_P2 may be disposed closer to the upper surface of the first redistribution structure 110 than a bottom surface of a pad insulation layer 121. The semiconductor package according to some embodiments may have a step where the second portion 125a_P2 and the pad insulation layer 121 meet, but the invention is not limited thereto.

The third portion 125a_P3 may overlap the hole HL in the third direction (Z direction). The third portion 125a_P3 may overlap the line portion LP in the third direction (Z direction), but the invention is not limited thereto, it may also overlap the line portion LP in the third direction (Z direction).

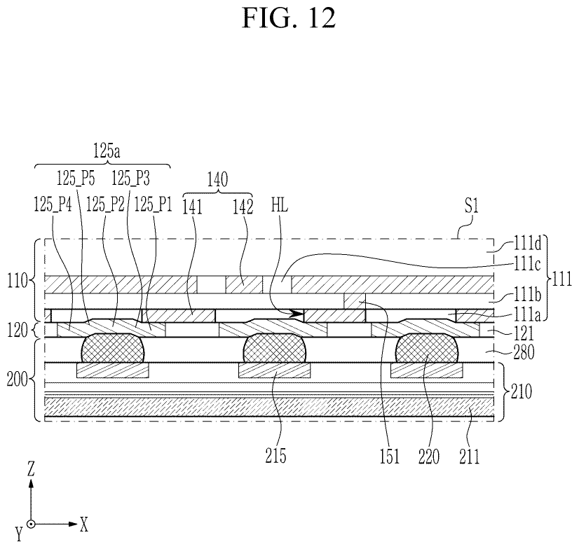

Referring to FIG. 12, a first conductive pad 125a of a semiconductor package according to some embodiments may include a first portion 125a_P1 overlapping a line portion LP in a third direction (Z direction), a second portion 125a_P2 overlapping a hole HL in a third direction (Z direction), and a third portion 125a_P3 disposed between the first portion 125a_P1 and the second portion 125a_P2 and inclined from an upper surface of the first redistribution structure 110. The description of the first portion 125a_P1 to the third portion 125a_P3 is substantially the same as the description of the first portion 125a_P1 to the third portion 125a_P3 of the embodiment of FIG. 11, and therefore repetitive description will be omitted.

In addition, the first conductive pad 125a of the semiconductor package according to some embodiments may further include a fourth portion 125a_P4 that overlaps the hole HL in the third direction (Z direction) and is disposed at the same height as the first portion 125a_P1, and a fifth portion 125a_P5 that is disposed between the fourth portion 125a_P4 and the second portion 125a_P2 and is inclined from the upper surface of the first redistribution structure 110.

The fourth portion 125a_P4 may be disposed at a different height from the second portion 125a_P2. For example, an upper surface of the fourth portion 125a_P4 may be disposed further from an upper surface of the first redistribution structure 110 than an upper surface of the second portion 125a_P2, and a bottom surface of the fourth portion 125a_P4 may be disposed further from the upper surface of the first redistribution structure 110 than a bottom surface of the second portion 125a_P2. In some embodiments, the bottom surface of the fourth portion 125a_P4 may be disposed at the same level as a bottom surface of a pad insulation layer 121.

Referring to FIG. 13, a first insulation layer 111a of a semiconductor package according to some embodiments may include different materials than second to fourth insulation layers 111a to 111d.

In some embodiments, the first insulation layer 111a may include a first material, and the second to fourth insulation layers 111a to 111d may include a second material different from the first material. In this case, the elastic modulus of the first material may be less than or equal to the elastic modulus of the second material. In addition, the first insulation layer 111a includes a different material from the pad insulation layer 121, and the elastic modulus of the first material constituting the first insulation layer 111a may be smaller than or equal to the elastic modulus of the material constituting the pad insulation layer 121.

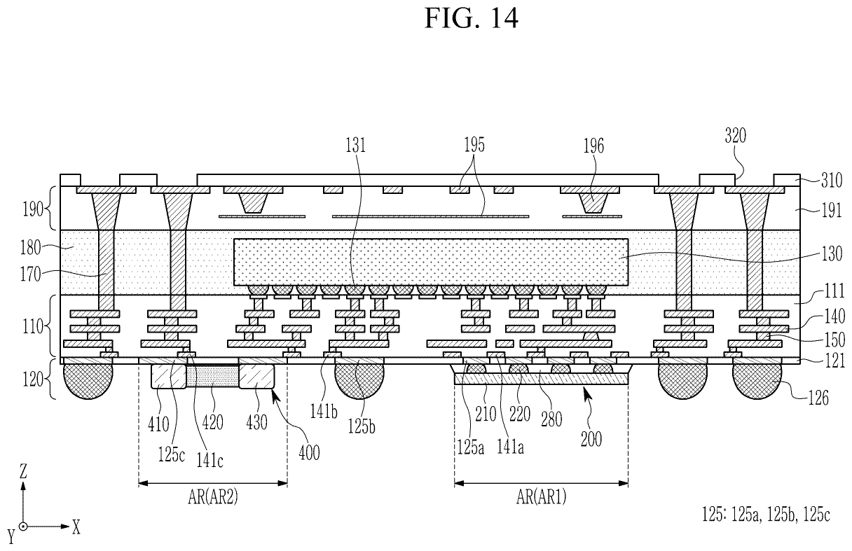

Hereinafter, referring to FIG. 14, semiconductor packages according to some embodiments will be described.

FIG. 14 is a cross-sectional view of a semiconductor package according to some embodiments.

The embodiment illustrated in FIG. 14 is substantially the same as the embodiment illustrated in FIG. 1 to FIG. 7, and therefore a repetitive description thereof will be omitted and differences will be mainly explained.

Referring to FIG. 14, first redistribution patterns 141 may include first redistribution sub-patterns 141a, second redistribution sub-patterns 141b and third redistribution sub-patterns 141c. The first and third redistribution sub-patterns 141a and 141c may be disposed in first and second mounting regions AR1 and AR2. The second redistribution sub-patterns 141b may be disposed on the main bumps 126.

The structure, the shape, and the layout relationship of components or elements in the region S1 FIG. 1 to FIG. 7 may be the same as those of corresponding components or elements (e.g., first conductive pads 125a and the first redistribution sub-patterns 141a) in a first mounting region AR1 of FIG. 14.

In other regions than the first mounting region AR1 of FIG. 14, the configuration of connection between the external connection structure 120 and the first redistribution structure 110 may be different from that described in connection with FIG. 1 to FIG. 7. For example, the second and third redistribution sub-patterns 141b and 141c may be electrically connected to and in contact with second conductive pads 125b and third conductive pads 125c, respectively.

For example, a part of the first conductive pad 125a may overlap a hole HL of the first redistribution sub-pattern 141a, and the remaining part may overlap a line portion LP. The first conductive pad 125a may overlap the first insulation layer 111a disposed within the hole HL having a relatively small elastic modulus and the line portion LP having a relatively large elastic modulus in the third direction (Z direction).

Similarly, in some embodiments, the third redistribution sub-pattern 141c disposed in the second mounting region AR2 may include a line portion LP and a hole HL disposed within the line portion LP.

In addition, the third conductive pad 125c to which an electronic element 400 is connected overlaps the hole HL of the third redistribution sub-pattern 141c, and the remaining part may overlap the line portion LP. The third conductive pad 125c may overlap the first insulation layer 111a disposed in the hole HL having a relatively small elastic modulus and the line portion LP having a relatively large elastic modulus in the third direction (Z direction).

In some embodiments, the second redistribution sub-pattern 141b connected to the second conductive pad 125b may include a line portion LP and a hole HL disposed within the line portion LP.

In addition, the second conductive pad 125b, to which an external device (e.g., a board on which a semiconductor package is mounted) is connected, may overlap the hole HL of the second redistribution sub-pattern 141b, and the remaining portion may overlap the line portion LP. The second conductive pad 125b may overlap the first insulation layer 111a disposed within the hole HL having a relatively small elastic modulus and the line portion LP having a relatively large elastic modulus in the third direction (Z direction).

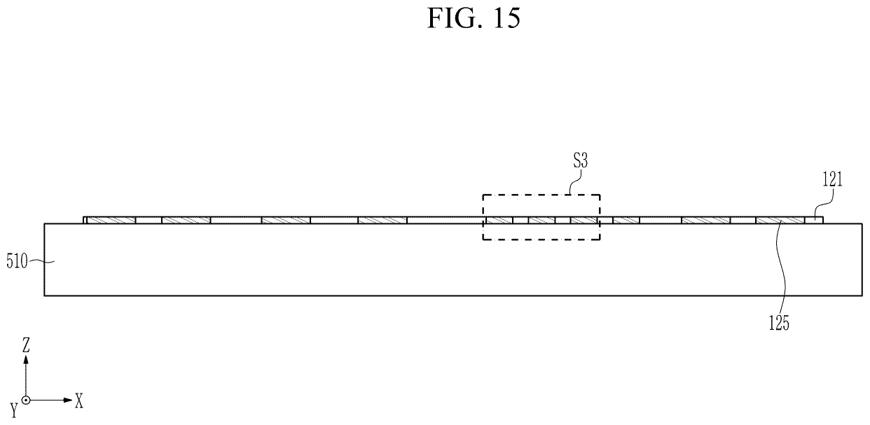

Accordingly, when the passive element 200 and/or electronic element 400 are connected to the external connection structure 120, or the external connection structure 120 is mounted on an external device and the like, the first insulation layer 111a disposed within the hole HL may be easily deformed in response to external pressure (e.g., mounting pressure MP of FIG. 7) as compared to the line portion LP, and cracks can be prevented from occurring within the semiconductor package according to some embodiments. Accordingly, the reliability of the semiconductor package can be improved. Hereinafter, a manufacturing method of a semiconductor package according to an embodiment will be described with reference to FIG. 15 to FIG. 25.

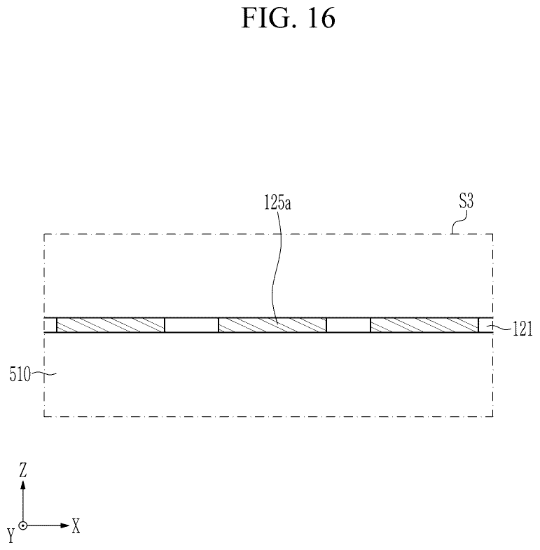

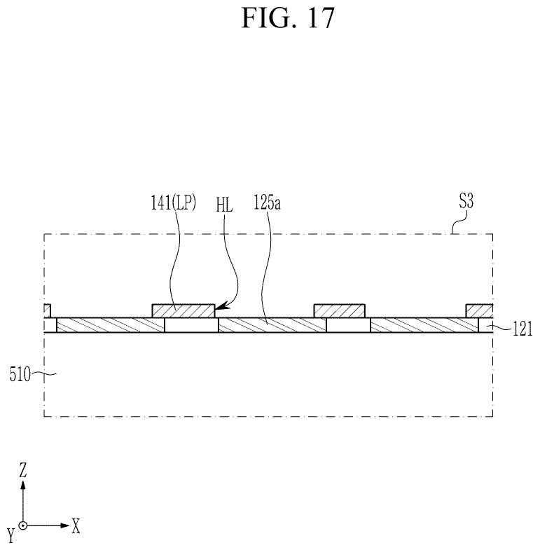

FIG. 15 to FIG. 25 are cross-sectional views illustrating a manufacturing method of a semiconductor package of an embodiment. FIG. 16 is an enlarged cross-sectional view of the region S3 of FIG. 15. FIG. 17 to FIG. 19 are cross-sectional views corresponding to the region S3 of FIG. 15, illustrating the manufacturing method of the semiconductor package of an embodiment.

Referring to FIG. 15 to FIG. 16, a first carrier substrate 510 may be prepared, and conductive pads 125 and a pad insulation layer 121 may be formed on the first carrier substrate 510.

The first carrier substrate 510 may include, for example, a silicon-based material such as glass or silicon oxide, an organic material, or another material such as aluminum oxide, or any combination of these materials.

The conductive pads 125 and the pad insulation layer 121 may be formed on the first carrier substrate 510.

First, a first photoresist pattern containing an opening may be formed using a photolithography process. Specifically, a photoresist material layer is coated on the first carrier substrate 510. In an embodiment, the photoresist material layer may be formed through spin coating. In an embodiment, the photoresist material layer may include an organic polymer resin including a photoactive material. Next, the photoresist material layer may be exposed and developed to form the first photoresist pattern including the opening.

Next, the conductive pads 125 may be formed within the opening. In some embodiments, a barrier conductive layer may be formed prior to forming the conductive pads 125. The barrier conductive layer may be a plating seed layer for deposition of the conductive pads 125.

Next, the first photoresist pattern may be removed, and a pad insulation layer 121 may be formed within the space where the first photoresist pattern is removed. The pad insulation layer 121 may be disposed in the same layer as the conductive pads 125. The pad insulation layer 121 may include at least one of a silicon-based insulator such as silicon oxide or silicon nitride, and a polymer such as PBO, BCB or polyimide. For example, the pad insulation layer 121 may be formed of PSG or BPSG.

Referring to FIG. 17, a first redistribution pattern 141 may be formed on the pad insulation layer 121 and the conductive pads 125.

A process of forming the first redistribution pattern 141 may be carried out by patterning a photoresist material to form a second photoresist pattern including an opening, and then filling the opening with a conductive material. The process for forming the second photoresist pattern including the opening may be performed by the same manner as (or similar manner to) the process for forming the first photoresist pattern that is described in connection with FIG. 15 and FIG. 16.

The first redistribution pattern 141 may extend in one direction. For example, the first redistribution pattern 141 may extend along the first direction (X direction). In an embodiment, through the first redistribution pattern 141 a hole HL may be disposed.

The first redistribution pattern 141 (or a portion of the first redistribution pattern 141) may be a line portion LP surrounding the hole HL. The hole HL surrounded by line portion LP may have a circular segment shape on a plane.

In an embodiment, a portion of the first conductive pad 125a may overlap the hole HL in a third direction (Z direction), and a remaining portion may overlap the line portion LP in a third direction (Z direction). In this case, the area of a portion where the first conductive pad 125a overlaps the hole HL in the third direction (Z direction) may be larger than the area of a portion where the first conductive pad 125a overlaps the line portion LP in the third direction (Z direction). By this configuration, while securing a contact area between the first conductive pad 125a and the first redistribution pattern 141 (e.g., when a passive element 200 is mounted on the first conductive pad 125a in a subsequent process), the mounting pressure (MP of FIG. 7) applied within the passive element 200 can be reduced.

The first redistribution pattern 141 may include at least one of copper, aluminum, tungsten, nickel, gold, tin, titanium, and alloys thereof. The first redistribution pattern 141 has substantially the same features as those described in connection with FIG. 1 to FIG. 7, and repetitive description will be omitted.

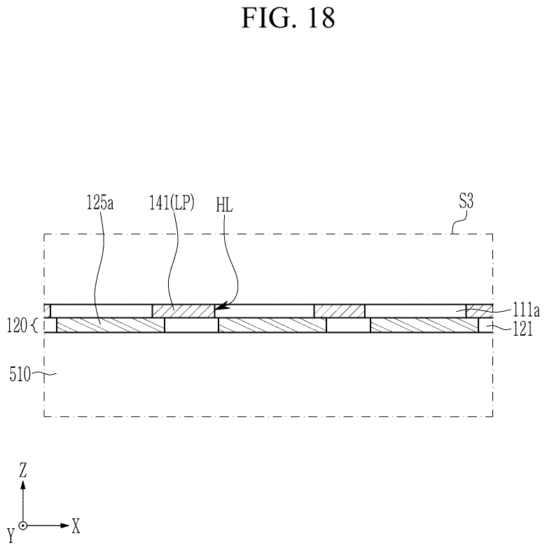

Referring to FIG. 18, a first insulation layer 111a may be formed on the pad insulation layer 121 and the conductive pads 125.

The first insulation layer 111a may be formed between the first redistribution pattern 141 and the hole HL. The first insulation layer 111a may be disposed in the same layer as the first redistribution pattern 141. For example, on a cross-section, an upper surface of the first redistribution pattern 141 may be disposed at substantially the same level as an upper surface of the first insulation layer 111a, and a bottom surface of the first redistribution pattern 141 may be disposed at substantially the same level as the bottom surface of the first insulation layer 111a. The upper surface of the first redistribution pattern 141 may be disposed at substantially the same distance from the upper surface of the first insulation layer 111a and an upper surface of the first carrier substrate 510. The bottom surface of the first redistribution pattern 141 may be disposed at substantially the same distance from the bottom surface of the first insulation layer 111a and the upper surface of the first carrier substrate 510. However, the invention is not limited thereto, depending on embodiments, the upper surface of the first redistribution pattern 141 may be disposed at a different level from the upper surface of the first insulation layer 111a.

The first insulation layer 111a may include insulating resin. The insulating resin may include a thermosetting resin such as epoxy resin, a thermoplastic resin such as polyimide, or a resin (e.g., photoactive resin such as prepreg, ABF, FR-4, BT, or photo-imageable dielectric (PID)) in which inorganic fillers and/or glass fibers (glass fiber, glass cloth, glass fabric) are impregnated.

In an embodiment, the first insulation layer 111a may include a material having an elastic modulus smaller than that of the first redistribution pattern 141. Accordingly, the first insulation layer 111a may be easily deformed in response to external pressure (e.g., mounting pressure MP of FIG. 7) as compared to the first redistribution pattern 141.

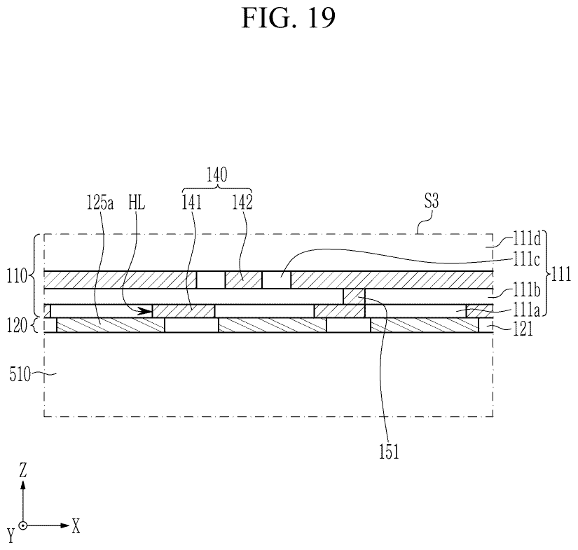

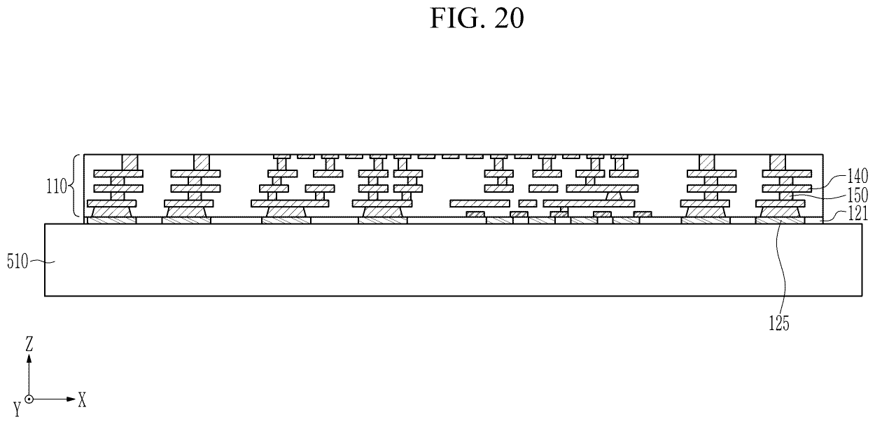

Referring to FIG. 19 and FIG. 20, a first redistribution structure 110 may be formed by forming a first redistribution via 151, a second insulation layer 111b, a second redistribution pattern 142, a third insulation layer 111c, and a fourth insulation layer 111d on a first insulation layer 111a. A process of forming the first redistribution via 151 and the second redistribution pattern 142 may be substantially the same as the process of forming the first redistribution pattern 141 as described in connection with FIG. 17. In addition, a process of forming the second insulation layer 111b, the third insulation layer 111c, and the fourth insulation layer 111d may be substantially the same as the process of forming the first insulation layer 111a described in connection with FIG. 18.

In FIG. 19, the first redistribution structure 110 is illustrated as including four insulation layers 111, but the invention is not limited thereto. For example, the first redistribution structure 110 may include five or more insulation layers 111. Alternatively, the first redistribution structure 110 may include three or less insulation layers 111. Depending on processes, boundaries between a plurality of insulation layers 111 may be unclear.

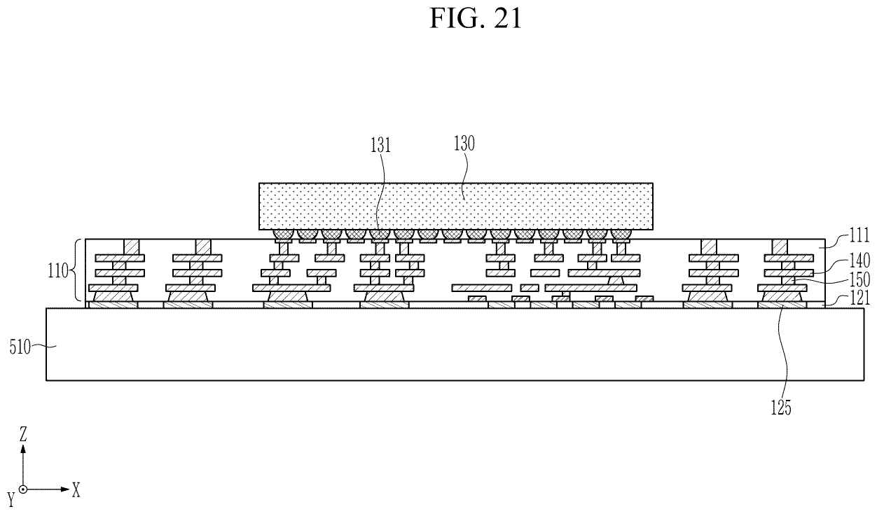

Referring to FIG. 21, a semiconductor chip 130 may be formed on the first redistribution structure 110. The semiconductor chip 130 may be bonded on the first redistribution structure 110. For example, the semiconductor chip 130 is electrically connected to the first redistribution structure 110 via a connection member 131. In the drawing, only one semiconductor chip 130 is illustrated, but the invention is not limited thereto, and a plurality of semiconductor chips may be arranged. In an embodiment, the connection member 131 may include a micro bump.

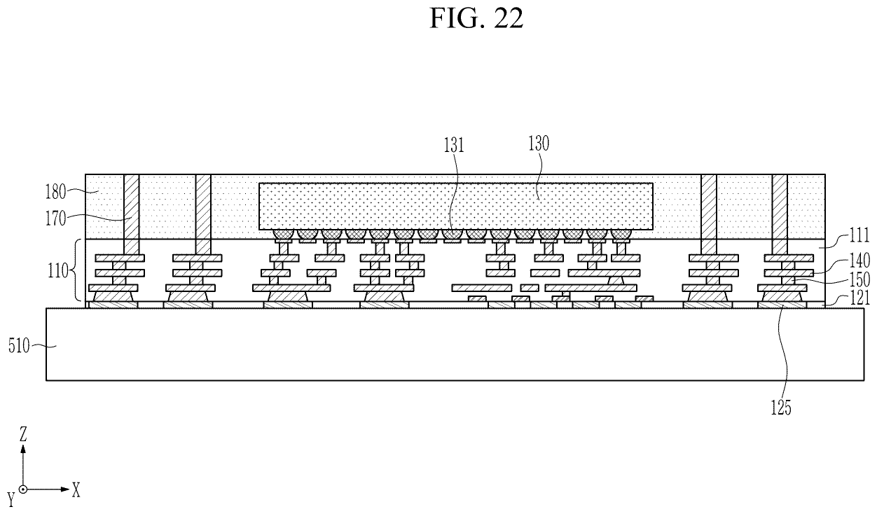

Referring to FIG. 22, a conductive post 170 and a molding member 180 may be formed on a first redistribution structure 110.

For example, the conductive post 170 may be formed to extend along the third direction (Z direction) on the first redistribution structure 110. In an embodiment, the conductive post 170 may be formed by performing a sputtering process. In another embodiment, the conductive post 170 may be formed by performing an electrolytic plating process after forming a seed metal layer. In an embodiment, the conductive post 170 may include at least one of copper, aluminum, tungsten, nickel, gold, silver, chromium, antimony, tin, titanium, and alloys thereof.

A molding member 180 may be formed to cover the semiconductor chip 130 and the conductive post 170. As an embodiment, a molding process may be performed such that the molding member 180 may include a compression molding or transfer molding process. The process of forming the molding member 180 may include a process of forming a molding material to cover the semiconductor chip 130 and the conductive post 170, and then planarizing an upper surface of the molding member 180 by performing chemical mechanical polishing (CMP).

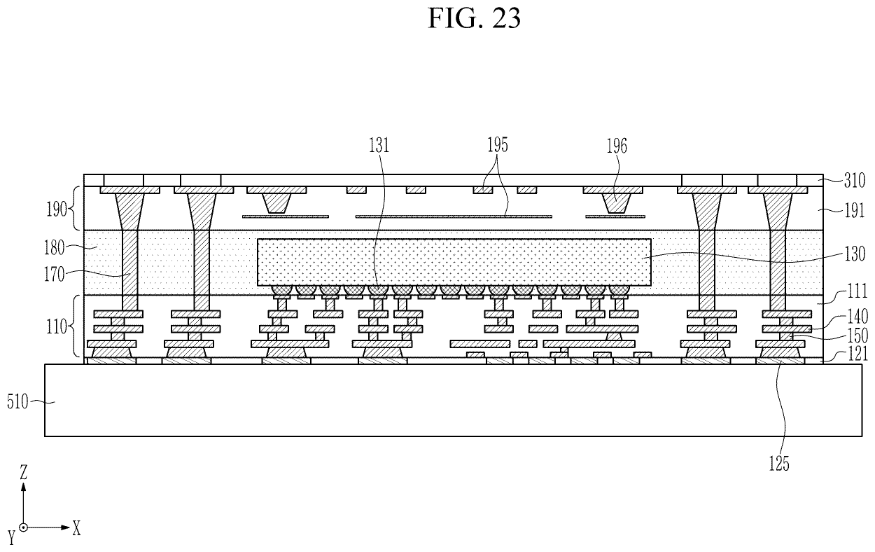

Referring to FIG. 23, a second redistribution structure 190 may be formed on the molding member 180.

The second redistribution structure 190 may be formed on the molding member 180 and the conductive post 170. The second redistribution structure 190 may be formed through substantially the same process as the first redistribution structure 110 described above. Accordingly, the second redistribution structure 190 may include an upper insulation layer 191, a plurality of upper redistribution patterns 195, and a plurality of upper redistribution vias 196 for electrical connections between the plurality of upper redistribution patterns 195.

In an embodiment, a capping layer 310 may be further formed on the second redistribution structure 190. The capping layer 310 may cover the upper surface of the second redistribution structure 190. In some embodiments, the capping layer 310 may include an opening, and external components may be electrically connected to the second redistribution structure 190 through the opening.

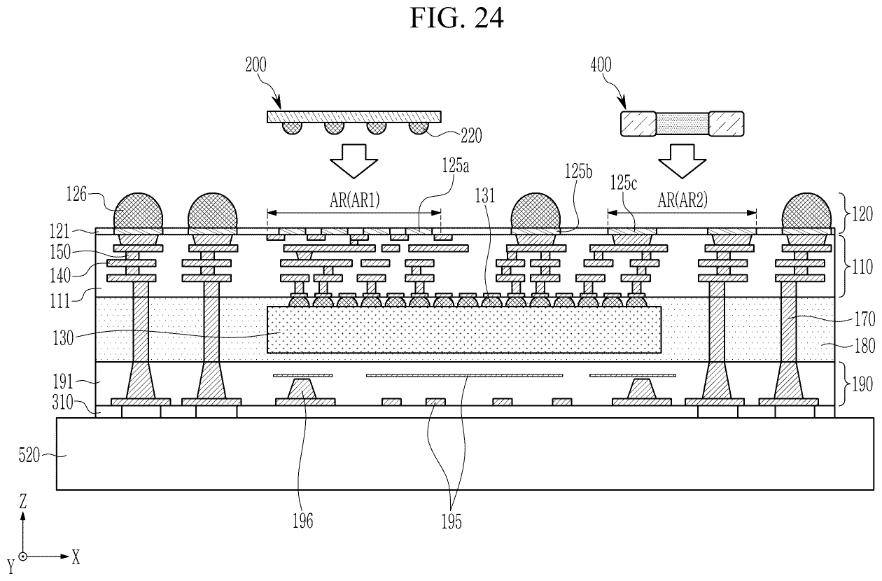

Referring to FIG. 24, after forming a second carrier substrate 520 on the capping layer 310, the first carrier substrate 510 may be removed, a main bump 126 may be formed, and a passive element 200 and/or an electronic element 400 may be mounted on the conductive pads 125.

For example, the second carrier substrate 520 may be formed on the capping layer 310, and the first carrier substrate 510 disposed on the bottom surface of the conductive pads 125 and the bottom surface of the pad insulation layer 121 may be removed. Accordingly, the bottom surface of the conductive pads 125 and the bottom surface of the pad insulation layer 121 may be exposed. After that, the resultant structure may be rotated (or turned over).

Next, the main bump 126 may be formed on at least a portion of the conductive pads 125. For example, the main bump 126 may be formed on the exposed second conductive pad 125b. The main bump 126 may include, for example, a solder ball, a solder bump.

Next, the passive element 200 may be mounted on the first conductive pad 125a in a first mounting region AR1.

The chip bump 220 of the passive element 200 is connected to the first conductive pad 125a and may be electrically connected to the first redistribution structure 110.

A portion of the first conductive pad 125a of the semiconductor package according to an embodiment may overlap the hole HL in the third direction (Z direction), and the remaining portion may overlap the line portion LP in the third direction (Z direction). The elastic modulus of a material constituting the first insulation layer 111a disposed within the hole HL may be smaller than the elastic modulus of a material constituting the first redistribution pattern 141. The first conductive pad 125a may overlap the first insulation layer 111a having a relatively small elastic modulus and the line portion LP having a relatively large elastic modulus in the third direction (Z direction).

Accordingly, when the passive element 200 is mounted on the first conductive pad 125a, the first insulation layer 111a disposed within the hole HL can be easily deformed in response to external pressure (e.g., mounting pressure MP of FIG. 7) as compared to the line portion LP. Accordingly, the pressure applied within the passive element 200 of the semiconductor package according to an embodiment can be reduced, and cracks can be prevented from occurring within the passive element 200. Accordingly, the reliability of the semiconductor package according to an embodiment can be improved.

In addition, the electronic element 400 may be mounted on conductive pads 125 positioned in a second mounting region AR2.

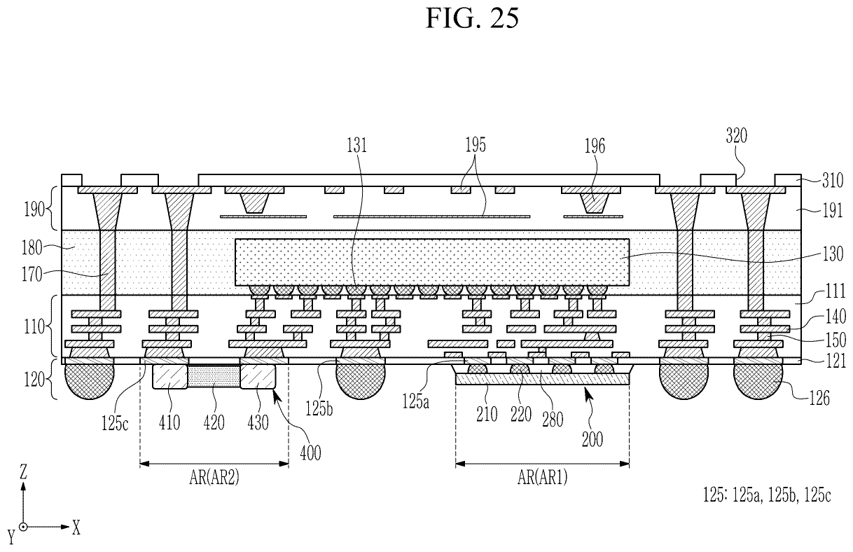

Referring to FIG. 25, the second carrier substrate 520 may be removed and the resultant structure may be rotated to form the semiconductor package of the embodiment of FIG. 1 to FIG. 7.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

### DESCRIPTION OF SYMBOLS

110: first redistribution structure
141: first redistribution pattern
111a: first insulation layer
120: external connection structure
125a: first conductive pad
121: pad insulation layer
130: semiconductor chip
170: conductive post
180: molding member
190: second redistribution structure

What is claimed is:

1. A semiconductor package comprising:
a first redistribution layer including a first redistribution pattern, through which a hole penetrates;
a semiconductor chip disposed on the first redistribution layer;
a first conductive pad disposed on a bottom surface of the first redistribution layer; and
a passive device connected to the first conductive pad,
wherein, with respect to a top down view:
a first part of the first conductive pad overlaps the hole, and the remaining part of the first conductive pad overlaps a peripheral portion of the first redistribution pattern, and
the peripheral portion surrounds the hole.

2. The semiconductor package of claim 1, wherein the hole has a circular segment shape with respect to a top down view.

3. The semiconductor package of claim 1, wherein, with respect to a top down view, at least a part of a side wall of the hole is curved.

4. The semiconductor package of claim 3, wherein:
the first redistribution pattern extends in a first direction, and
a maximum width of the hole in the first direction is greater than 57 μm and less than 79.5 μm.

5. The semiconductor package of claim 4, wherein a maximum width of the hole along a second direction intersecting the first direction is greater than a maximum width of the first conductive pad along the second direction.

6. The semiconductor package of claim 1, wherein, with respect to a top down view:
the first part of the first conductive pad occupies a first area,
the remaining part of the first conductive pad occupies a second area, and
the first area is larger than the second area.

7. The semiconductor package of claim 1, wherein at least a portion of the first conductive pad is in contact with a bottom surface of the peripheral portion.

8. The semiconductor package of claim 1, wherein a bottom surface of the first part of the first conductive pad is closer to an upper surface of the first redistribution layer than a bottom surface of the remaining part.

9. The semiconductor package of claim 8, wherein a boundary between the first part and the remaining part of the first conductive pad is inclined with respect to the upper surface of the first redistribution layer.

10. The semiconductor package of claim 1, wherein:
the first redistribution layer comprises a first insulation layer that fills the hole, and
the first part of the first conductive pad contacts the first insulation layer.

11. The semiconductor package of claim 10, further comprising a pad insulation layer disposed on the bottom surface of the first redistribution layer and surrounding the first conductive pad,
wherein an elastic modulus of the first insulation layer is equal to or smaller than an elastic modulus of the pad insulation layer.

12. The semiconductor package of claim 10, wherein the first redistribution layer further comprises:
a second insulation layer that is disposed on the first insulation layer;
a third insulation layer that is disposed on the second insulation layer; and
a second redistribution pattern that penetrates the third insulation layer and is disposed on the second insulation layer and electrically connected to the first redistribution pattern, and
the hole overlaps the second insulation layer and the third insulation layer with respect to a top down view.

13. The semiconductor package of claim 1, wherein the passive device may be a capacitor including a porous layer.

14. The semiconductor package of claim 13, wherein:
the passive device further comprises a conductive terminal connected to the first conductive pad, and
the conductive terminal completely overlaps the first conductive pad with respect to a top down view.

15. The semiconductor package of claim 14, wherein at least a portion of the conductive terminal overlaps the hole with respect to a top down view.

16. A semiconductor package comprising:
a first redistribution layer;
a semiconductor chip disposed on the first redistribution layer;
a first conductive pad that contacts a bottom surface of the first redistribution layer; and
a passive device connected to the first conductive pad,
wherein the first redistribution layer comprises:
a first redistribution pattern, through which a hole penetrates, and
a first insulation layer that fills the hole,
wherein a first portion of the first conductive pad is in contact with a bottom surface of the first insulation layer positioned within the hole,
wherein the remaining portion of the first conductive pad is in contact with a bottom surface of a peripheral portion of the first redistribution pattern, and
wherein the peripheral portion surrounds the hole with respect to a top down view.

17. The semiconductor package of claim 16, wherein, with respect to a top down view:
the hole has a circular segment shape, and
the first conductive pad has a circular shape.

18. The semiconductor package of claim 16, wherein, with respect to a top down view:
the first portion of the first conductive pad occupies a first area,
the remaining portion occupies a second area, and
the first area is larger than the second area.

19. The semiconductor package of claim 16, wherein a distance between an upper surface of the first insulation layer and an upper surface of the first redistribution layer is the same as a distance between an upper surface of the first redistribution pattern and the upper surface of the first redistribution layer.

20. A semiconductor package comprising:
a first redistribution layer;
a first chip disposed on a first surface of the first redistribution layer;
a second redistribution layer disposed on the first chip;
a conductive post that connects the first redistribution layer and the second redistribution layer;
a first conductive pad and a second conductive pad disposed on the first redistribution layer;
a second chip disposed on a second surface of the first redistribution layer; and
a first conductive terminal protruding from a bottom surface of the second conductive pad,
wherein the first and second surfaces of the first redistribution layer faces away from each other,
wherein the second chip includes a second conductive terminal connected to the first conductive pad,
wherein the first redistribution layer comprises:
a first redistribution pattern, through which a hole penetrates, and
a first insulation layer disposed in the hole and including a material having an elastic modulus smaller than an elastic modulus of the first redistribution pattern, and
wherein, with respect to a top down view, a portion of the first conductive pad overlaps the first insulation layer disposed within the hole, and the remaining portion of the first conductive pad overlaps a peripheral portion of the first redistribution pattern, and the peripheral portion surrounds the hole.
